(19) United States
(12) Patent Application Publication
(10) Pub. No.: US 2024/0172511 A1
(43) Pub. Date: May 23, 2024

(54) DISPLAY DEVICE

(71) Applicant: Japan Display Inc., Tokyo (JP)

(72) Inventor: Sho YANAGISAWA, Tokyo (JP)

(73) Assignee: Japan Display Inc., Tokyo (JP)

(21) Appl. No.: 18/504,200

(22) Filed: Nov. 8, 2023

(30) Foreign Application Priority Data
Nov. 18, 2022 (JP) 2022-185174

(51) Int. Cl. H10K 59/131

(52) U.S. Cl. CPC H10K 59/1315

(57) ABSTRACT

A display device includes a plurality of transistors having an oxide semiconductor layer, a first terminal electrically connected to the plurality of transistors, a second terminal electrically connected to the plurality of transistors and adjacent to the first terminal, a first wiring electrically connected to the plurality of transistors and the first terminal and located between the plurality of transistors and the first terminal, and a second wiring electrically connected to the plurality of transistors and the second terminal and located between the plurality of transistors and the second terminal, wherein the first wiring is formed of a metallic material, and the second wiring includes an oxide conductive layer having the same composition as the oxide semiconductor layer.

### CROSS-REFERENCE TO RELATED APPLICATION

This application claims the benefit of priority to Japanese Patent Application No. 2022-185174 filed on Nov. 18, 2022, the entire contents of which are incorporated herein by reference.

### FIELD

An embodiment of the present invention relates to a display device.

### BACKGROUND

A display device using an element utilizing organic electroluminescence (EL) or a liquid crystal element or the like for a display region has, for example, a configuration in which a display region and a plurality of terminals are arranged in a substrate. The plurality of terminals is electrically connected to pixels of the display region by wiring which connects a pixel arranged in the display region with the plurality of terminals, and various signals (for example, an image signal or a control signal) or power source potentials are input thereto. In such a wiring, a metallic film such as aluminum, copper, titanium, molybdenum, or chromium may be used (for example, WO2013/021866).

In recent years, the number of wirings to which various types of signals or power source potentials are input to a display device tends to increase in order to realize high-definition images. A display device arranged with the plurality of terminals tends to provide a wide display region by narrowing the region around the display region. Due to these trends, a method in which the lead wiring is arranged obliquely from the inside of the display region to the terminals is adopted. In such a wiring, a defect such as a wiring forming defect tends to occur, and various methods for the extraction wiring are required for high definition and narrowing of the frame.

An object of one embodiment of the present invention is to provide a display device with less defects and suppressed deterioration. Another object of one embodiment of the present invention is to provide a high-yield display device.

### SUMMARY

A display device according to an embodiment of the present invention includes: a plurality of transistors having an oxide semiconductor layer; a first terminal electrically connected to the plurality of transistors; a second terminal electrically connected to the plurality of transistors and adjacent to the first terminal; a first wiring electrically connected to the plurality of transistors and the first terminal and located between the plurality of transistors and the first terminal; and a second wiring electrically connected to the plurality of transistors and the second terminal and located between the plurality of transistors and the second terminal, wherein the first wiring is formed of a metallic material, and the second wiring includes an oxide conductive layer having the same composition as the oxide semiconductor layer.

### DESCRIPTION OF THE DRAWINGS

FIG. 1 is a schematic top view showing a configuration of a display device according to an embodiment of the present invention.

FIG. 2A is a block diagram showing a pixel circuit of a display device according to an embodiment of the present invention.

FIG. 2B is a block diagram showing a pixel circuit of a display device according to an embodiment of the present invention.

FIG. 3 is a schematic top view showing a terminal of a display device and its periphery according to an embodiment of the present invention.

FIG. 4 is a schematic top view showing a terminal of a display device and its periphery according to an embodiment of the present invention.

FIG. 5 is a schematic end view showing a terminal of a display device and its periphery according to an embodiment of the present invention.

FIG. 6A is a schematic end view showing a configuration of a display device according to an embodiment of the present invention.

FIG. 6B is a schematic end view showing a method for manufacturing a display device according to an embodiment of the present invention.

FIG. 6C is a schematic end view showing a method for manufacturing a display device according to an embodiment of the present invention.

FIG. 6D is a schematic end view showing a method for manufacturing a display device according to an embodiment of the present invention.

FIG. 6E is a schematic end view showing a method for manufacturing a display device according to an embodiment of the present invention.

FIG. 6F is a schematic end view showing a method for manufacturing a display device according to an embodiment of the present invention.

FIG. 6G is a schematic end view showing a method for manufacturing a display device according to an embodiment of the present invention.

FIG. 6H is a schematic end view showing a method for manufacturing a display device according to an embodiment of the present invention.

FIG. 6I is a schematic end view showing a method for manufacturing a display device according to an embodiment of the present invention.

FIG. 6J is a schematic end view showing a method for manufacturing a display device according to an embodiment of the present invention.

FIG. 6K is a schematic end view showing a method for manufacturing a display device according to an embodiment of the present invention.

FIG. 6L is a schematic end view showing a method for manufacturing a display device according to an embodiment of the present invention.

FIG. 7 is a schematic top view showing a terminal of a display device and its periphery according to an embodiment of the present invention.

FIG. 8 is a schematic top view showing a terminal of a display device and its periphery according to an embodiment of the present invention.

FIG. 9 is a schematic end view showing a terminal of a display device and its periphery according to an embodiment of the present invention.

FIG. 10 is a schematic top view showing a terminal of a display device and its periphery according to an embodiment of the present invention.

FIG. 11 is a schematic top view showing a terminal of a display device and its periphery according to an embodiment of the present invention.

FIG. 12 is a schematic top view showing a terminal of a display device and its periphery according to an embodiment of the present invention.

FIG. 13 is a schematic top view showing a terminal of a display device and its periphery according to an embodiment of the present invention.

FIG. 14A is a schematic end view of a periphery of a terminal of a display device according to an embodiment of the present invention.

FIG. 14B is a schematic end view of a periphery of a terminal of a display device according to a comparative embodiment.

Hereinafter, each embodiment of the present invention will be described with reference to the drawings. The following disclosure is merely an example. A configuration that can be easily conceived by a person skilled in the art by appropriately changing the configuration of the embodiment while keeping the gist of the invention is naturally included in the scope of the present invention. In order to make the description clearer, the drawings, the width, the layer thickness, the shape, and the like of each part may be schematically represented in comparison with an actual embodiment. However, the illustrated shapes are merely examples, and do not limit the interpretation of the present invention. In the present specification and the drawings, the same reference signs are given to elements similar to those described previously with respect to the above-described drawings, and a detailed description thereof may be omitted as appropriate.

A “semiconductor device” refers to any device that can function by utilizing semiconductor properties. A transistor and a semiconductor circuit are one form of the semiconductor device. For example, the semiconductor device may be an integrated circuit (IC) such as a display device or a micro-processing unit (MPU), or a transistor used in a memory circuit.

The “display device” refers to a structure that displays an image using an electro-optic layer. For example, the term display device may refer to a display panel including the electro-optic layer, or may refer to a structure with other optical members (for example, a polarizing member, a backlight, a touch panel, and the like) attached to a display cell. The “electro-optic layer” may include a liquid crystal layer, an electroluminescence (EL) layer, an electrochromic (EC) layer, or an electrophoretic layer, as long as there is no technical contradiction. Therefore, although the display device according to the embodiment described later will be described by exemplifying a liquid crystal display device including a liquid crystal layer and an organic EL display device including an organic EL layer, the structure according to the present embodiment can be applied to a display device including other electro-optic layers described above.

In each embodiment of the present invention, a direction from a substrate toward an oxide semiconductor layer is referred to as “on” or “above”. Conversely, a direction from the oxide semiconductor layer toward the substrate is referred to as “under” or “below”. In this way, for convenience of explanation, although the phrase “above” or “below” is used for the purpose of description, for example, the upper and lower relationship between the substrate and the oxide semiconductor layer may be arranged so as to be opposite to those shown in the drawings. In the following explanation, for example, the expression “an oxide semiconductor layer on a substrate” merely describes the upper and lower relationship between the substrate and the oxide semiconductor layer as described above, and another member may be arranged between the substrate and the oxide semiconductor layer. The terms “above” or “below” mean a stacking order in which a plurality of layers is stacked, and may be a positional relationship in which a transistor and a pixel electrode do not overlap each other in a plan view when expressed as a pixel electrode above a transistor. On the other hand, when expressed as a pixel electrode vertically above a transistor, it means a positional relationship in which the transistor and the pixel electrode overlap each other in a plan view.

In this specification, the expressions “α includes A, B or C,” “α includes any of A, B, or C,” and “α includes one selected from a group consisting of A, B, and C,” and the like do not exclude the case where α includes a plurality of combinations of A to C unless otherwise indicated. Furthermore, these expressions do not exclude the case where α includes other elements.

### FIRST EMBODIMENT

### 1. Configuration of Display Device

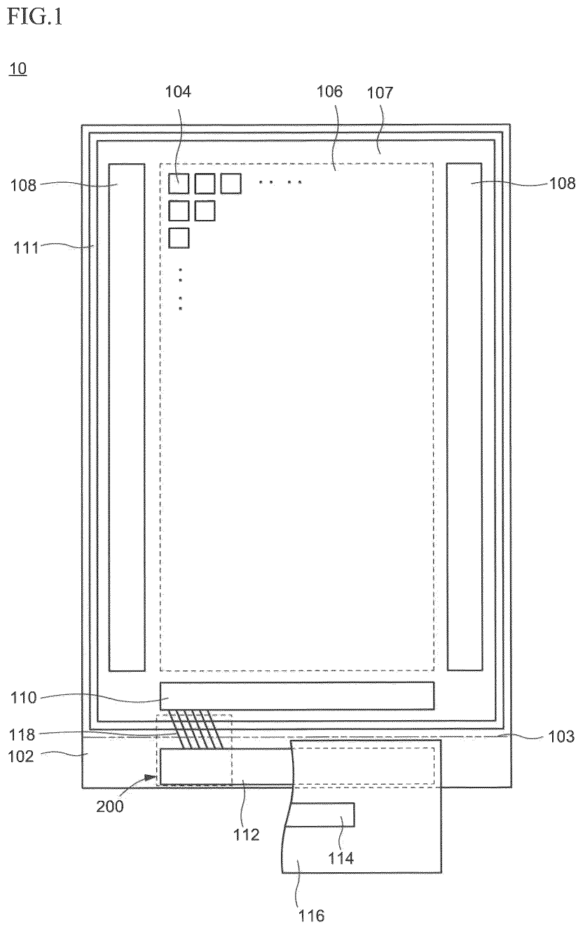

FIG. 1 shows a schematic top view of the display device 10 according to an embodiment of the present invention. As shown in FIG. 1, the display device 10 includes the substrate 102 and the counter substrate 103, and the plurality of the pixels 104 are arranged on the substrate 102. A single region containing the plurality of the pixels 104 and the surrounding region are defined as the display region 106 and the peripheral region 107 of the substrate 102, respectively.

The peripheral region is arranged with a driving circuit for driving the pixel 104. In the embodiment shown in FIG. 1, the two scanning line driving circuits 108 sandwiching the display region 106 and the signal line driving circuit 110 including an analog switch or the like are arranged. When a liquid crystal element is arranged in the display device 10, the seal 111 is arranged so as to surround these structures. The seal 111 secures the substrate 102 and the counter substrate 103 such that the substrate 102 and the counter substrate 103 sandwich the liquid crystal layer. From the display region 106, the scanning line driving circuit 108, and the signal line driving circuit 110, the wiring 118 extends to one side of the substrate 102 and is exposed at an end portion of the substrate 102 to form the terminal 112. The wiring 118 is located between the display region 106 and the terminal 112. The wiring 118 is located between the scanning line driving circuit 108 and the signal line driving circuit 110 and the terminal 112. The terminal 112 shown in FIG. 1 includes the plurality of the terminals 112, which will be described in detail later. The terminal 112 is electrically connected to the connector 116, such as a flexible printed circuit (FPC) substrate. The driver IC 114 for controlling the pixel 104 may be further mounted on the connector 116 or on the substrate 102. The signal line driving circuit 110 may not be arranged on peripheral region, and this function may be realized by the driver IC 114.

In the following explanation, for convenience, the terminal 112 side of the display device 10 is defined as a lower portion, and the opposite side of the terminal 112 is defined as an upper portion. When the substrate 102 or the display region 106 can be regarded as a quadrangle mainly composed of four sides, the side on the side of the terminal 112 is called the lower side and the side opposite the terminal 112 is called the upper side.

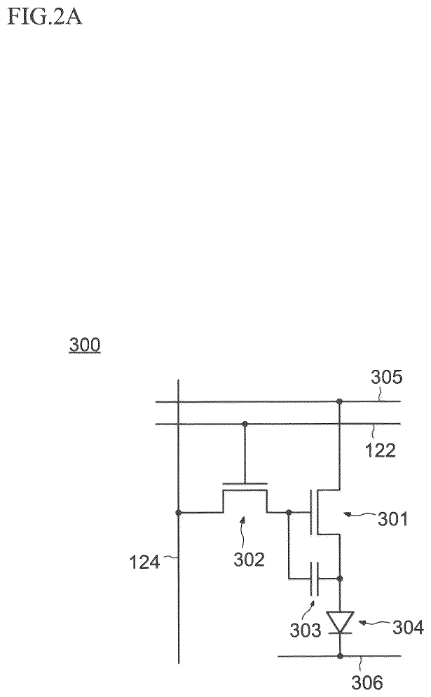

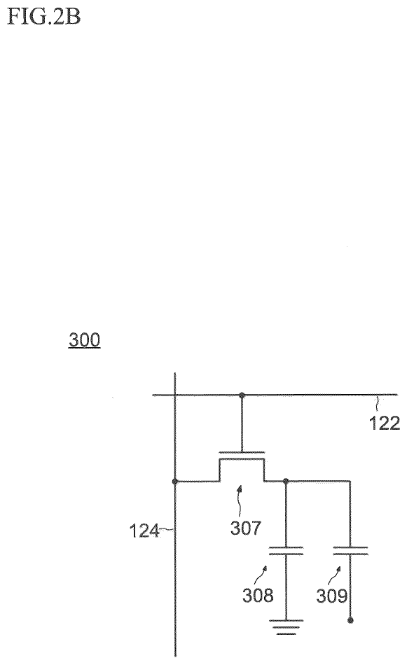

Here, the pixel circuit 300 for controlling the individual pixels 104 will be described with reference to FIG. 2A and FIG. 2B. FIG. 2A shows an example of a pixel circuit using a light emitting element using organic electroluminescence (organic EL element) in the pixel 104. FIG. 2B also shows an example of a pixel circuit that uses a liquid crystal element in the pixel 104.

### 2. Pixel

### 2-1. Pixel Circuit 1

FIG. 2A shows the configuration of the pixel circuit 300 in the display device 10 of one embodiment of the present invention. For convenience of explanation, a basic configuration using two semiconductor devices (thin-layer transistors) will be described by way of example. As shown in FIG. 2A, the pixel circuit 300 includes elements such as the driving transistor 301, the selection transistor 302, the storage capacitor 303, and a light emitting element 304. The driving transistor 301 and selection transistor 302 are formed of a semiconductor device such as a thin-layer transistor.

The driving transistor 301 is connected to the anode power source line 305, and the driving transistor 301 is connected to one end (anode) of the light emitting element 304. The other end (cathode) of the light emitting element 304 is connected to a cathode power source line 306. In the present embodiment, the anode power source line 305 is supplied with a higher power source voltage than the cathode power source line 306. In FIG. 1, the anode power source line 305 is not shown.

The gate of the selection transistor 302 is connected the scanning line 122 and the source of the selection transistor 302 is connected to the data signal line 124. The drain of the selection transistor 302 is connected to the gate of the drive transistor 301. The source and drain of the selection transistor 302 may be switched depending on the relationship between the voltage applied to the data signal line 124 and the voltage stored in the storage capacitor 303.

The storage capacitor 303 is connected to the gate and the drain of the driving transistor 301 and the drain of selection transistor 302. A video signal is supplied to the data signal line 124, and a grayscale signal for determining the emission intensity of the light emitting element 304 is supplied. The scanning line 122 is supplied with a scan signal for selecting a pixel for writing a grayscale signal.

Next, referring to FIG. 2B, an example of a pixel circuit in which a liquid crystal element is used for the pixel 104 will be described.

### 2-2. Pixel Circuit 2

FIG. 2B is a block diagram showing a pixel circuit of a display device according to an embodiment of the present invention. As shown in FIG. 2B, the pixel circuit 300 includes elements such as the transistor 307, the storage capacitor 308, and the liquid crystal element 309. The transistor 307 is composed of a semiconductor device such as a thin film transistor.

The gate of the transistor 307 is connected to the scanning line 122, and the source of the transistor 307 is connected to the data signal line 124. The drain of the transistor 307 is connected to the storage capacitor 308 and the liquid crystal element 309. Although not shown, one electrode of the storage capacitor 308 is connected to the drain of the transistor 307, and the other electrode is connected to a common electrode of the pixel 104. One electrode of the liquid crystal element 309 is connected to the drain of the transistor 307 via a pixel electrode, and the other electrode is connected to a common electrode. The source and drain of the transistor 307 may be switched depending on the relationship between the voltage applied to the data signal line 124 and the voltage stored in the storage capacitor 308.

Returning to the description in FIG. 1, the plurality of the terminals 112 is electrically connected to the connector 116. Each of the plurality of the terminals 112 is electrically connected to the transistor 307 or the signal line driving circuit 110 and the scanning line driving circuit 108 of the pixel 104 via the wiring 118. The plurality of the terminals 112 receives a signal or a power source potential supplied from the connector 116. The signal is a signal for operating the transistor of the pixel 104, and is, for example, an image signal indicating an image to be displayed on the display region 106 or a control signal for controlling the scanning line driving circuit 108 or the signal line driving circuit 110. The number of terminals 112 included in the display device 10 may be any number as long as the number is plural.

The connector 116 outputs a signal input from an external circuit (not shown) to the terminals 112. The connector 116 may be configured with a plurality of wirings arranged on a flexible substrate. Each of the plurality of wirings is electrically connected to any one of the terminals 112.

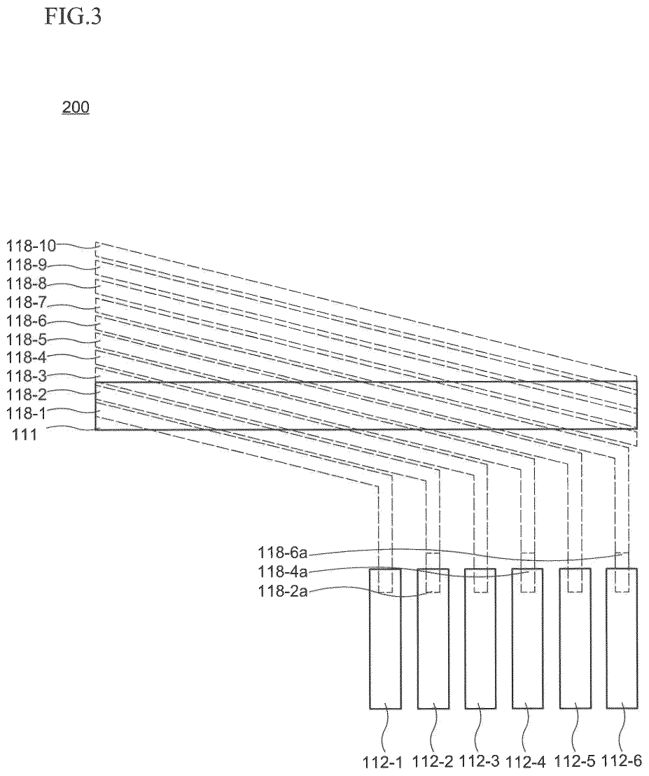

Referring now to FIG. 3, the wiring 118 for electrically connecting the terminal 112 and the transistors or the scanning line driving circuit 108 or the signal line driving circuit 110 arranged in the display region 106 will be described.

### 3. Terminal Peripheral Structure

### 3-1. Wiring 1

FIG. 3 is a top view showing a terminal of a display device and its periphery according to an embodiment of the present invention. Specifically, FIG. 3 shows the wiring 118 connected to the terminal 112 and the terminal 112 in the region 200 enclosed by dashed lines shown in FIG. 1. For convenience of explanation, the configuration between substrate 102 and the counter substrate 103, the connector 116, and the like are omitted in FIG. 3, and the terminal 112 and the wiring 118 will be described.

The plurality of the wirings 118 is arranged so as to diagonally straddle the seal 111. The wirings 118 are arranged to overlap with the seal 111, Each of the plurality of the wirings 118 is directly or electrically connected to the terminal 112. The same signal or the same power source potential is input to the adjacent terminals. For example, a video signal is input to the terminal 112-1, the terminal 112-2, the terminal 112-3, the terminal 112-4, the terminal 112-5, and the terminal 112-6.

The terminals 112-1, 112-2, 112-3, 112-4, 112-5, and 112-6 may be connected to the wiring 118-1, the wiring 118-2, the wiring 118-3, the wiring 118-4, the wiring 118-5, and the wiring 118-6, respectively. These wirings may be electrically connected to the data signal line 124, for example, as described above.

It is possible to change the type of wiring 118 configured according to the supplied signal. For example, the wiring 118-1 to the wiring 118-6 can each be made of the same metallic material as the scanning line 122. The wiring 118-1 to the wiring 118-6 can use wiring having the same composition as the active layer of the transistor that constitutes the pixel 104 or the scanning line drive circuit 108 or the signal line drive circuit 110, respectively. As will be described later, an active layer of the transistor is made of a material having a higher light transmittance than wiring formed of a metallic material.

Here, when the liquid crystal element 309 is used in the display device 10 as described above, in order to sandwich a liquid crystal layer between the substrate 102 and the counter substrate 103, the seal 111 is disposed so as to surround the display region 106. Since the wiring 118 is disposed between the terminal 112 disposed on the end portion of the substrate 102 and the display region 106, it overlaps with the seal 111 surrounding the display region 106. The seal 111 is usually made of a light-curing resin, as will be described in detail later. Light to cure the seal 111 is irradiated onto the seal 111 from the opposite side of the substrate 102 where the transistors are formed.

Light to cure the seal 111 can pass through the wiring 118-2, the wiring 118-4, and the wiring 118-6 which have high light transmittance. Accordingly, the light to cure the seal 111 is applied to the seal 111 that overlaps the wiring 118-2, the wiring 118-4, and the wiring 118-6. As shown in FIG. 3, since the wiring 118-1, the wiring 118-3, the wiring 118-5 and the wiring 118-2, the wiring 118-4, and the wiring 118-6 formed of metallic material are arranged alternately or side by side, scattered light of light passing through the wiring 118-2, the wiring 118-4, and the wiring 118-6 with high light transmittance can irradiate the seal 111.

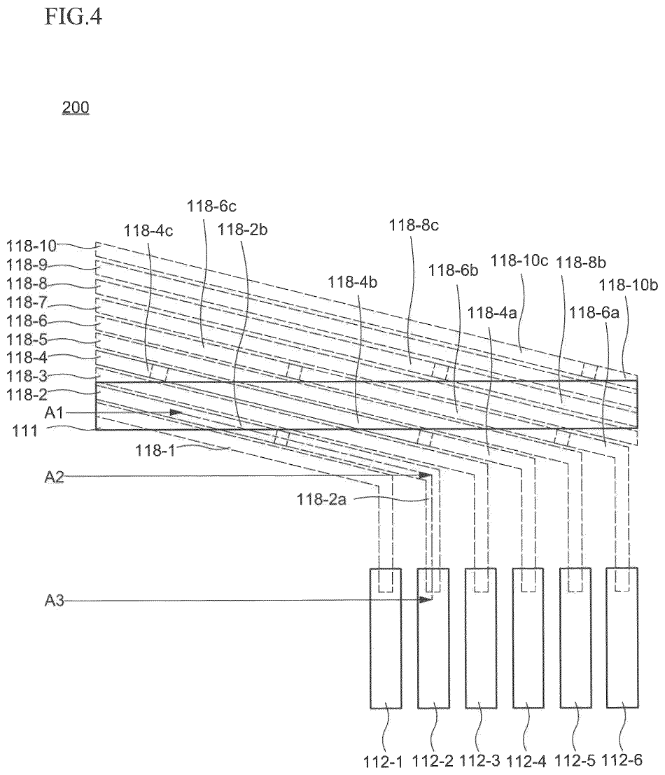

Referring now to FIG. 4, the wiring 118 using a wiring with high light transmittance only where it overlaps the seal 111 will now be described.

### 3-2. Wiring 2

FIG. 4 is a top view showing a terminal of a display device and its periphery according to an embodiment of the present invention. Specifically, FIG. 4 shows an example in which the wiring 118-2 is composed of the wiring 118-2a and the wiring 118-2c, which are made of a metallic material, and the wiring 118-2b with high light transmittance.

The wiring 118-2 that has high transmittance in the region that overlaps the seal 111 uses the wiring 118-2b. The wiring 118-2b is located between the wiring 118-2a made of a metallic material and the wiring 118-2c made of a metallic material. The wiring 118-2a made of a metallic material is connected to the terminal 112-2. The wiring 118-2c made of a metallic material is directly or electrically connected to the pixel 104 or a transistor constituting the scanning line driving circuit 108 or the signal line driving circuit 110.

The wiring 118-4, the wiring 118-6, the wiring 118-8, and the wiring 118-10 can also use the same configuration as the wiring 118-2. As shown in FIG. 4, when the wiring 118 made of a metal material and the wiring 118 with high light transmittance are alternately arranged or arranged adjacent to each other in a portion overlapping the seal 111, the light irradiated from the surface where the transistor of the substrate 102 is not arranged can reach the seal 111 overlapping the wiring 118 made of the metal material. Since there is at least a small difference in wiring resistance between the wiring 118 with high light transmittance and the wiring 118 made of a metallic material, the difference between the wiring resistance of the wiring 118-1 and the wiring 118-2 can be reduced by using the wiring 118b with high light transmittance only in the part of the wiring 118 that overlaps the seal 111 and by using the wiring 118-2a and the wiring 118-2c formed in the same manner as the wiring 118-1, which is made of a metallic material, in other portions. Therefore, it is possible to reduce wiring resistance variation between the wiring 118-1 and the wiring resistance of the wiring 118-2.

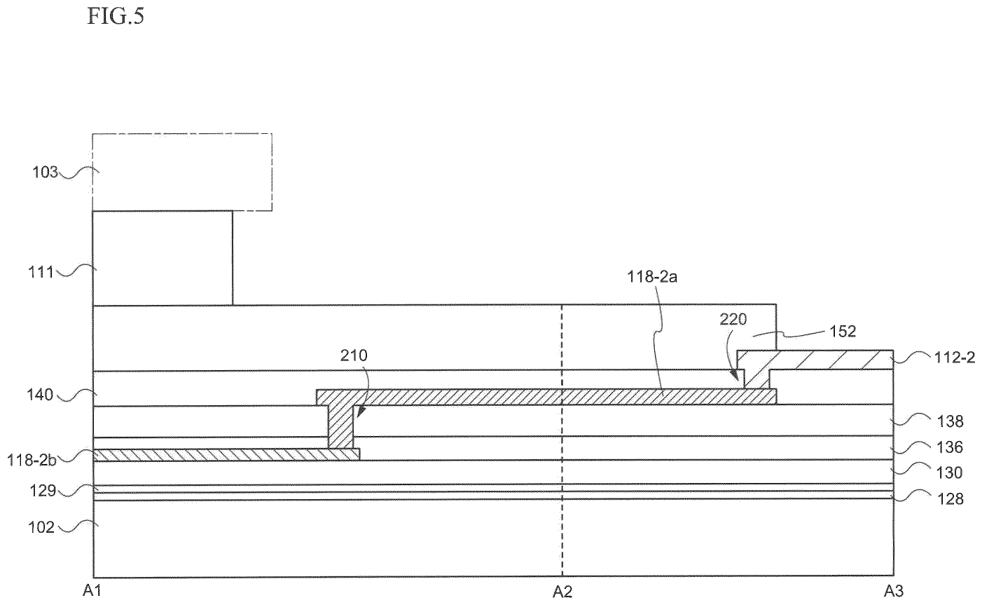

Referring to FIG. 5, a cross-sectional configuration of the 118-2 using the wiring 118-2b with high light wiring transmittance in the part overlapping the seal 111 will be described.

FIG. 5 is an end view showing a terminal of a display device and its periphery according to an embodiment of the present invention. Specifically, FIG. 5 corresponds to an end view showing a cross section taken along A1-A3 of FIG. 4.

The display device 10 has the substrate 102. The substrate 102 has the function of supporting the circuit formed thereon and may include glass, quartz, or polymers. By using a polymer such as polyimide, polyamide, or polycarbonate for the substrate 102, flexibility can be applied to the display device 10, and a so-called flexible display can be arranged.

The base film 128 may be arranged on the substrate 102. the base film 128 can prevent contamination from the substrate 102, for example, and an inorganic insulating material can be used. As the inorganic insulating material, for example, silicon nitride, silicon oxide, and composites thereof can be used. As shown in FIG. 5, the base film 129 may be arranged on the base film 128 and the base film may have a stacked structure.

The insulating layer 130 may be arranged on the base film 129. The insulating layer 130 can be formed by the same process as the insulating layer arranged between the bottom gate electrode of the transistor and the active layer when the bottom gate structure or the dual gate structure is employed in the transistor arranged in the display region 106. The insulating layer 130 may be made of the same material as that of the base film 128.

The wiring 118-2b may be arranged on the insulating layer 130. The wiring 118-2b may be the same as the active layer of the transistor arranged in the display region 106. The wiring 118-2b can be formed in the same step as the step of forming the active layer of the transistor arranged in the display region 106. As the active layer of the transistor, an oxide semiconductor layer can be used, and an oxide semiconductor layer can be used for the wiring 118-2b by reducing resistance, as will be described later. Therefore, the wiring 118-2b is an oxide conductive layer having the same composition as the active layer of the transistor arranged in the display region 106.

The insulating layer 136 may be arranged on top of the wiring 118-2b and the insulating layer 130. When the transistor arranged in the display region 106 has a top-gate structure or a dual-gate structure, the insulating layer 136 can be formed in the same step as the step of forming the gate insulating layer arranged between the active layer and the gate electrode of the transistor. The insulating layer 136 may be made of the same material as that of the base film 128.

The insulating layer 138 may be arranged on the insulating layer 136. The insulating layer 138 may be a single-layer structure or a stacked structure. For example, silicon nitride, silicon oxide, or the like can be used for the insulating layer 138.

The wiring 118-2a may be arranged on the insulating layer 138. The wiring 118-2a can be connected to the wiring 118-2b through the opening 210 formed in the insulating layer 138 and the insulating layer 136 that reaches the wiring 118-2b and through the opening 210. The wiring 118-2a can be formed in the same step as the step of forming the source electrode and the drain electrode of the transistor arranged in the display region 106. The wiring 118-2a can be formed using a common metallic material. For example, aluminum (Al), titanium (Ti), chromium (Cr), cobalt (Co), nickel (Ni), molybdenum (Mo), hafnium (Hf), tantalum (Ta), tungsten (W), bismuth (Bi), silver (Ag), copper (Cu), and alloys or compounds thereof can be used as the metal material. The wiring 118-2a may have a single-layer structure or may be a stacked structure.

The insulating layer 140 may be arranged on top of the wiring 118-2a and the insulating layer 138. The Insulating layer 140 may be made of the same material as that of the base film 128.

The terminal 112-2 may be arranged on the insulating layer 140. The terminal 112-2 has the opening 220 that reaches the wiring 118-2a formed in the insulating layer 140, and can be connected to the wiring 118-2a through the opening 220. As shown in FIG. 5, the terminal 112-2 has a portion exposed from the insulating layer 152, and the exposed portion may be connected to the driver IC 114. Aa material used for the wiring 118-2a may be used for the terminal 112-2.

The insulating layer 152 may be arranged on the insulating layer 134. The insulating layer 152 may be arranged on the terminal 112-2 such that the terminal 112-2 is partially exposed as described above. A light emitting element or liquid crystal element arranged in the pixel 104 is formed on the insulating layer 152. A photosensitive organic resin material including an acryl resin, a polysiloxane, a polyimide, a polyester, or the like can be used as the insulating layer 152, and can function as an organic insulating layer.

The seal 111 may be arranged on the insulating layer 152. As shown in FIG. 5, it is arranged so as to overlap the wiring 118-2b. Since the wiring 118-2b has high light transmittance, as described above, it is possible to transmit the light irradiated toward the seal 111 from the surface opposite to the surface on which the base film 128 of the substrate 102 is arranged. For example, a photocurable resin can be used for the seal 111.

The counter substrate 103 is not shown in FIG. 4, but may be arranged over the seal 111 as shown in FIG. 5. The counter substrate 103 is disposed opposite the substrate 102. The counter substrate 103 may be the same as the substrate 102.

As described above, the wiring 118-2 is made of the wiring 118-2b which has high transmittance at a part overlapping the seal 111. Next, a transistor in which an active layer is formed in a process similar to that of the wiring 118-2b with high light transmittance will be described.

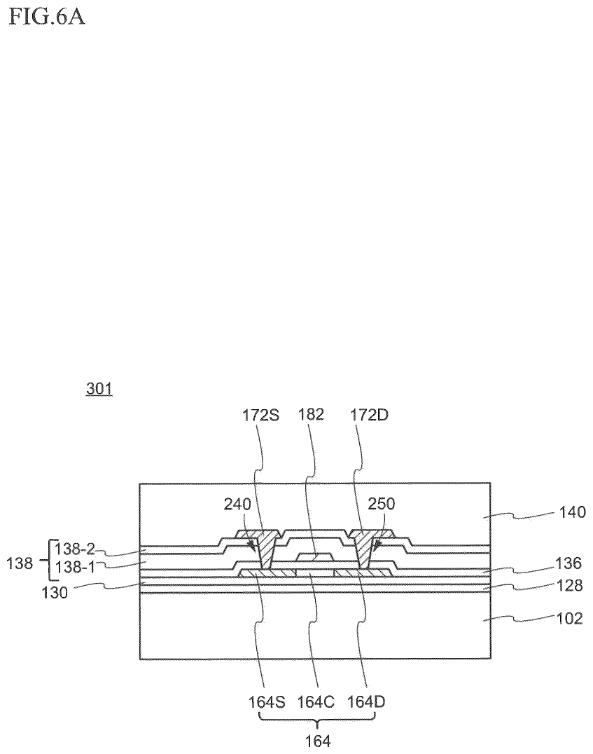

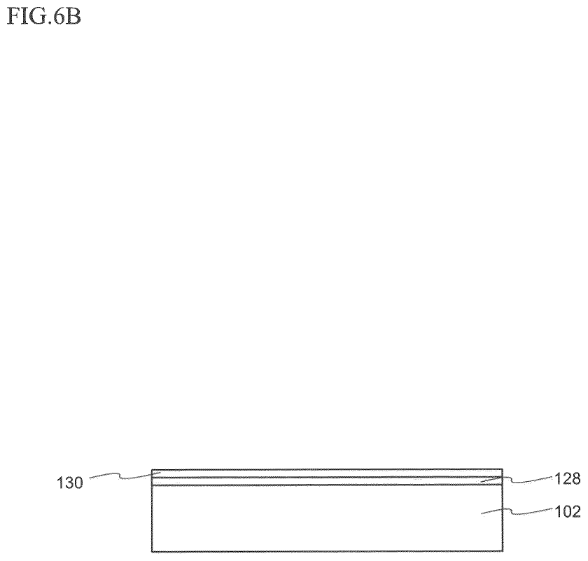

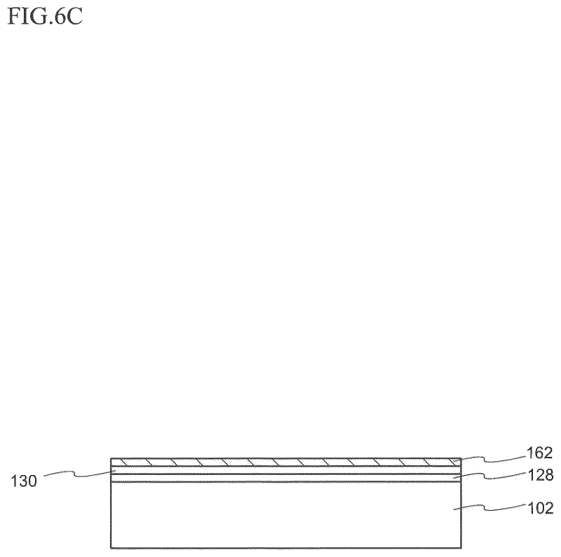

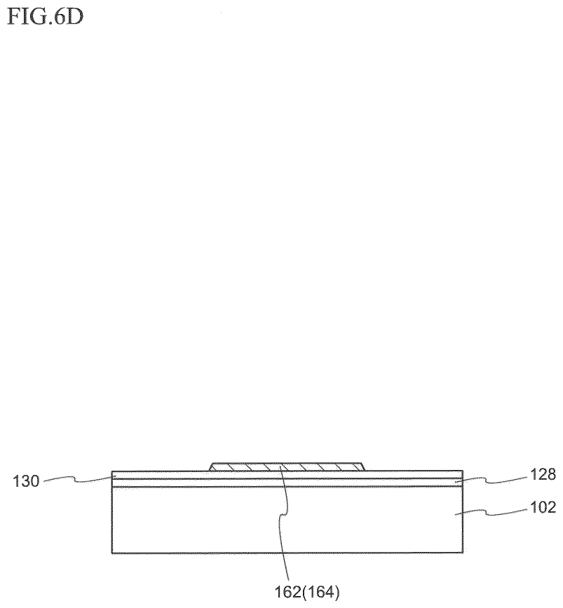

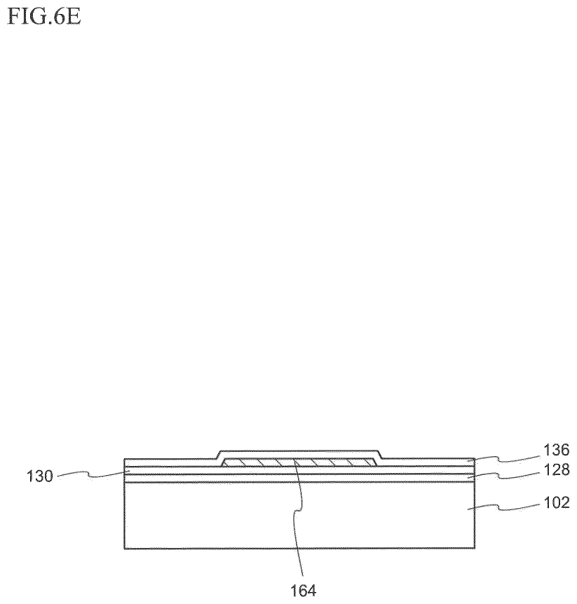

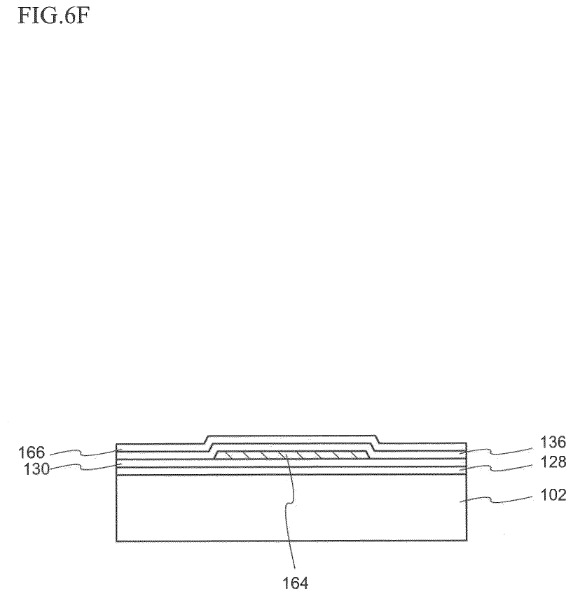

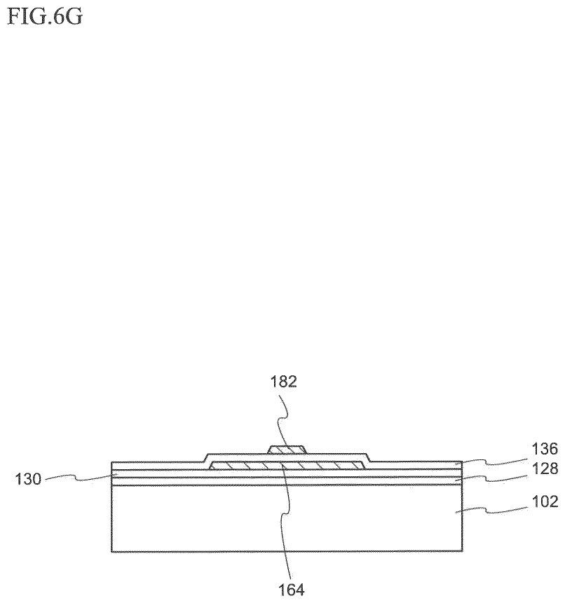

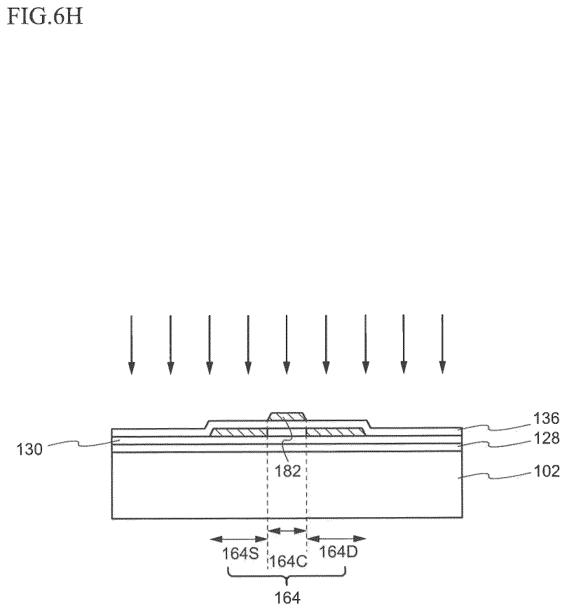

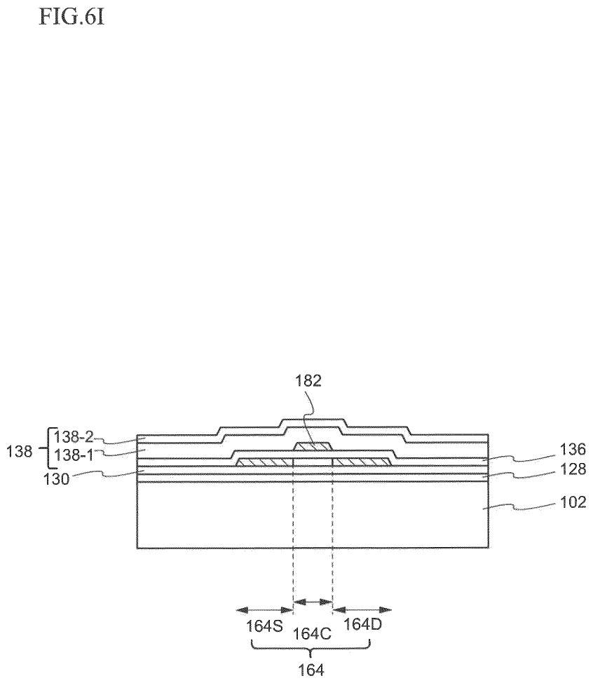

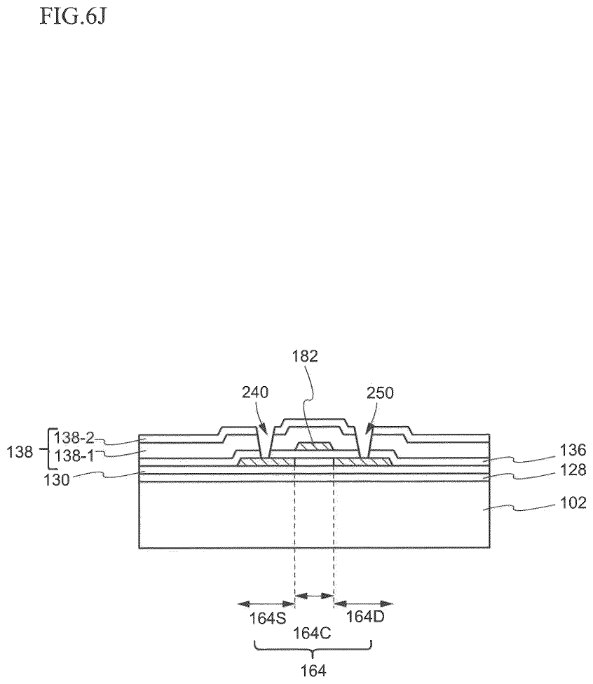

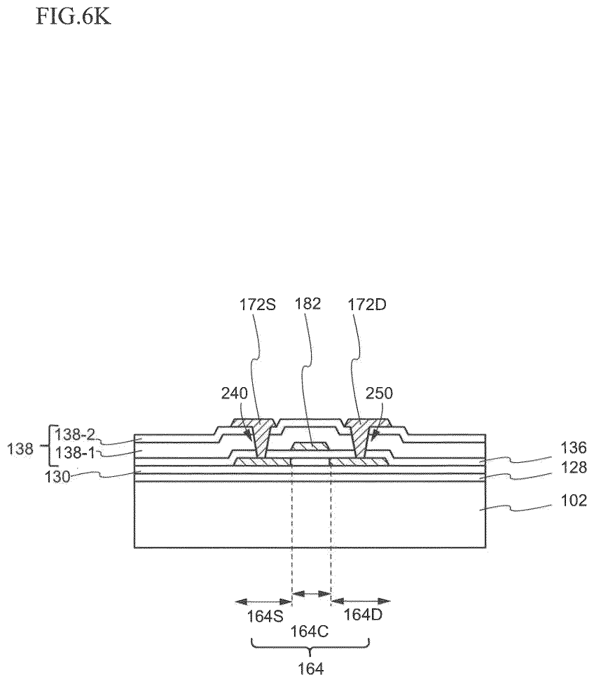

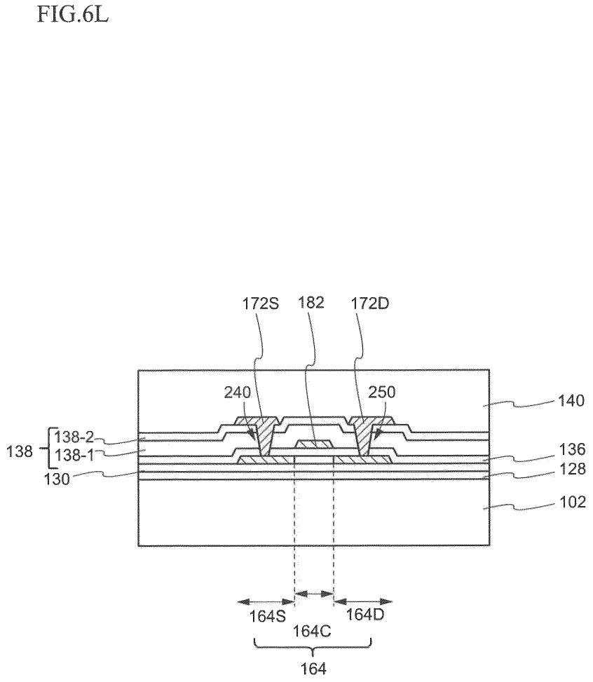

Referring to FIG. 6B to FIG. 6L an example of a manufacturing method for the transistor arranged in the display area 106 is described. FIG. 6B to FIG. 6L are end views showing a method for manufacturing a display device according to an embodiment of the present invention. The method of manufacturing transistors shown in FIGS. 6B to 6L is, for example, a method for manufacturing transistors related to the top-gate structure shown in FIG. 6A.

### 4. Method for Manufacturing Display Device

FIG. 6A is an end view showing a configuration of a display device according to an embodiment of the present invention. FIG. 6A shows that the transistor 301, the transistor 302, and the transistor 307 shown in FIG. 2A or FIG. 2B are transistors arranged in the signal line driving circuit 110 and the scanning line driving circuit 108. FIG. 6A shows, as an example, the transistor 301 shown in FIG. 2A.

As shown in FIG. 6A, the transistor includes the base film 128, the insulating layer 130, the oxide semiconductor layer 164, the gate insulating layer 136, the gate electrode 182, the insulating layer 138-1, the insulating layer 138-2, the source electrode 172S, and the drain electrode 172D on the substrate 102.

Next, a method for manufacturing the transistor 301 will be described.

The base film 128 and the insulating layer 130 are formed on the substrate 102, as shown in FIG. 6B.

Next, as shown in FIG. 6C, the oxide semiconductor layer 162 is formed on the insulating layer 130. The oxide semiconductor layer 162 may be made of a metal-oxide having semiconducting properties. For example, an oxide semiconductor containing two or more metals including indium (In) is used as the oxide semiconductor layer 162. The proportion of indium in the two or more metals is 50% or more. In addition to indium, gallium (Ga), zinc (Zn), aluminum (Al), hafnium (Hf), yttrium (Y), zirconia (Zr), or lanthanoids are used as the oxide semiconductor layer 162. Elements other than those described above may be used as the oxide semiconductor layer 162. In the present embodiment, a metallic oxide (oxide semiconductor based on In) containing indium and gallium (Ga) is used as the oxide semiconductor layers 162.

When the oxide semiconductor layer 162 is crystallized by baking the oxide semiconductor layer 162, the oxide semiconductor layer 162 after deposition and before baking should be amorphous (state with few crystal components of the oxide semiconductor). In other words, the deposition method of the oxide semiconductor layer 162 should be under conditions that prevent crystallization of the oxide semiconductor layer 162 as much as possible immediately after deposition. For example, when the oxide semiconductor layer 162 is deposited by a sputtering method, the oxide semiconductor layer 162 is deposited while controlling the temperature of an object to be deposited, for example, the substrate 102. In order to control the temperature of the object to be formed, for example, film formation is performed while cooling the object to be formed. For example, the temperature of the film-forming surface of the object to be formed (hereinafter, referred to as “film-forming temperature”) is 100° C., or less, 70° C., or less, 50° C., or less, or 30° C., or less, and it is preferable to cool the object to be formed from the surface opposite to the film-forming surface. By forming the oxide semiconductor layer 162 while the object to be formed is cooled as described above, the oxide semiconductor layer 162 with few crystalline components can be formed immediately after the film formation.

Next, a pattern of the oxide semiconductor layer 162 is formed as shown in FIG. 6D. The oxide semiconductor layer 162 should be patterned before the oxide semiconductor layer 162 is baked. When the oxide semiconductor layer 162 is crystallized by baking, it tends to be difficult to etch. Even if the oxide semiconductor layer 162 is damaged by etching, the damage can be repaired by baking the oxide semiconductor layer 162.

After the patterning of the oxide semiconductor layer 162, baking is performed on the oxide semiconductor layer 162. In the baking of the oxide semiconductor layer 162, the oxide semiconductor layer 162 is held at a predetermined attained temperature for a predetermined period of time. The predetermined reached temperature is 300° C., or more and 500° C., or less, preferably 350° C., or more and 450° C., or less. The holding time at the reached temperature is 15 minutes or more and 120 minutes or less, preferably 30 minutes or more and 60 minutes or less. By baking the oxide semiconductor layer 162, the oxide semiconductor layer 162 is crystallized to form the polycrystalline oxide semiconductor layer 164.

Next, as shown in FIG. 6E, the gate insulating layer 136 is formed on the oxide semiconductor layer 162. For the gate insulating layer 136, it is preferable to use a less defective insulating layer. The gate insulating layer 136 may be deposited at a deposition temperature of 350° C. or higher in order to form a less defective insulating layer. After the gate insulating layer 136 is deposited, an oxygen-implanting process may be performed on a portion of the gate insulating layer 136.

Next, as shown in FIG. 6F, the metal oxide layer 166 containing aluminum as a main component is formed on the gate insulating layer 136, baked, and then the metal oxide layer 166 is removed.

An inorganic insulating layer such as aluminum oxide (AlOx), aluminum oxynitride (AlOxNy), aluminum nitride oxide (AlNxOy), and aluminum nitride (AlNx) are used for the metal-oxide layer 166. Here, the ratio of aluminum contained in the metal oxide layer 166 may be 1% or more of the total amount of the metal oxide layer 166. The ratio of aluminum contained in the metal oxide layer 166 may be 5% or more and 70% or less, 10% or more and 60% or less, or 30% or more and 50% or less of the entire metal oxide layer 166.

The film thickness of the metal oxide layer 166 may be, for example, 5 nm or more and 100 nm or less, 5 nm or more and 50 nm or less, 5 nm or more and 30 nm or less, or 7 nm or more and 15 nm or less.

After the metal oxide layer 166 is formed, the metal oxide layer 166 is baked. After baking the metal oxide layer 166, the metal oxide layer 166 is removed. At least a part of the metal-oxide layer 166 overlapping oxide semiconductor layer 164 may be removed.

Next, as shown in FIG. 6G, the gate electrode 182 is formed on the gate insulating layer 136. The gate electrode 182 is formed to be in contact with the exposed gate insulating layer 136 by removing the metallic oxide layer 166. For example, aluminum (Al), titanium (Ti), chromium (Cr), cobalt (Co), nickel (Ni), molybdenum (Mo), hafnium (Hf), tantalum (Ta), tungsten (W), bismuth (Bi), silver (Ag), copper (Cu), and alloys or compounds thereof can be used as the gate electrode 182. The source region 164S and the drain region 164D of the oxide semiconductor layer 164 are formed. Specifically, an impurity element is implanted into the oxide semiconductor layer 164 through the gate insulating layer 136 using the gate electrode 182 as a mask by ion implantation or ion doping. For example, an impurity element such as argon (Ar), phosphorus (P), or boron (B) is implanted into a portion of the oxide semiconductor layer 164 not covered with the gate electrode 182. By implanting such impurities into a portion of the oxide semiconductor layer 164, the resistance of a portion thereof is reduced. Specifically, the oxide semiconductor layer 164 shown in FIG. 6H corresponds to a part of the oxide semiconductor layer 164 in which the source region 164S and the drain region 164D sandwiching the channel region 164C are not covered with the gate electrode 182, and the impurity elements are implanted. Since the channel region 164C of the oxide semiconductor layer 164 is covered with the gate electrode 182, no impurity elements are implanted.

Here, the wiring 118-2 shown in FIG. 4 and the wiring 118-2b shown in FIG. 5 are also formed in the same step as the active layer of the transistor 301. The wiring 118-2 and the wiring 118-2b are implanted into the entire wiring 118-2 and wiring 118-2b because there is no part of the transistor 301 covered by gate electrode. Therefore, the wiring 118-2 and the wiring 118-2b have the same composition as the oxide semiconductor layer 164, and are made to have low resistance by implantation of an impurity element, resulting in an oxide conductive layer. The wiring 118-2 and the wiring 118-2b, which are oxide conductive layers, contain the same impurity elements as the source region 164S and the drain region 164D because impurity elements are implanted in the same manner as the source region 164S and the drain region 164D of the oxide semiconductor layer 164 described above.

Next, as shown in FIG. 6I, the insulating layer 138-1 and the insulating layer 138-2 are formed on the gate electrode 182 and the gate insulating layer 136.

Next, as shown in FIG. 6J, the opening 240 and the opening 250 are formed in the gate insulating layer 136, the insulating layer 138-1, and the insulating layer 138-2. The opening 240 exposes the source region 164S and the opening 250 exposes the drain region 164D. When the source region 164S and the drain region 164D are exposed by the opening 240 and the opening 250, the source electrode 172S and the drain electrode 172D shown in FIG. 6K are formed.

The transistor 301 having a top gate structure can be formed through the above-described manufacturing process. When a transistor having a bottom gate structure and a dual gate structure is formed, a bottom gate electrode may be formed between the base film 128 and the insulating layer 130, and the insulating layer 130 may function as a gate insulating film between the bottom gate electrode and the oxide semiconductor layer 164.

When the display device 10 is mounted with an organic EL element or liquid crystal element, the insulating layer 152 shown in FIG. 5 is formed on the insulating layer 140 to form an organic EL element or liquid crystal element. As shown in FIG. 6L, the insulating layer 140 is formed over the insulating layer 132, the source-electrode 172S, and the drain-electrode 172D. The terminal 112-2 shown in FIG. 5 is formed on the insulating layer 140.

The wiring 118-2 and the wiring 118-2b can be formed together with the manufacturing steps of the transistors described above.

### 5. Modification of Wiring

5-1. First Modification

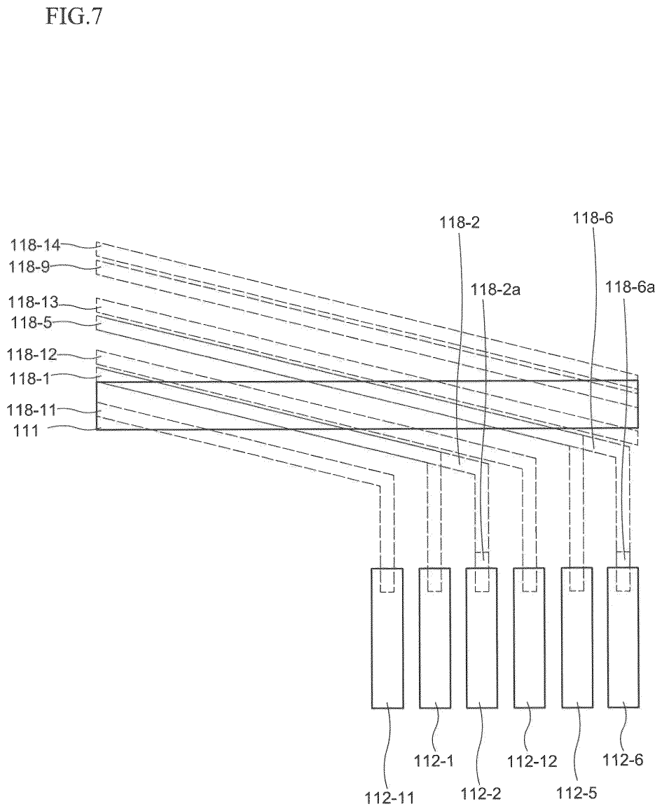

Referring to FIG. 7, a modification of the terminal of the display device 10 and its periphery will be described. FIG. 7 is an end view showing a method for manufacturing a display device according to an embodiment of the present invention. Specifically, a modification of the configuration of the terminal 112 and the wiring 118 in the region 200 surrounded by the broken line shown in FIG. 1 is shown. Configurations that are the same as or similar to those of the display device 10 shown in FIGS. 1 to 6 may be omitted.

The difference from the wiring 118 shown in FIG. 3 is that the wiring 118-1 connected to the terminal 112-1 overlaps the wiring 118-2 connected to the terminal 112-2 to which the video signal is supplied. Further, as shown in FIG. 7, the wiring 118-5 connected to the terminal 112-5 may also overlap the wiring 118-6 connected to the terminal 112-6 to which the video signal is supplied.

As shown in FIG. 7, wiring 118-1 overlaps wiring 118-2 in a portion that straddles the seal 111 and a portion that is disposed obliquely with respect to the seal 111. The wiring 118-1 is arranged so as to overlap the wiring 118-2, so that the terminal 112-1 and the wiring 118-11 connected to the adjacent terminal 112-11 can be arranged. At this time, since the wiring 118-11 is made of a metallic material, a distance is arranged between the wiring 118-11 and the wiring 118-1 even in a part overlapping the seal 111 and due to this distance, the light irradiated to cure the seal 111 passes between these wiring and sufficiently reaches the seal 111.

Any of the layers used in the manufacturing process of the display device 10 may be combined and used for the wiring 118. However, as shown in FIG. 7, when the wiring 118-2 is made of an oxide conductive layer, it is preferable that the scanning line driving circuit 108 or the scanning line 122 is not used for the wiring 118-1 that overlaps the scanning line driving circuit. In other words, if an oxide conductive layer is used for one of the overlapping wirings 118, the layer used for the other wiring 118 should not be the same layer that functions as the gate electrode of the transistor that constitutes the pixel 104 or the scanning line drive circuit 108 and the signal line drive circuit 110. The above-described configuration is not preferable because the wiring 118 may lose the function as a wiring when a layer that functions as a gate electrode of a transistor is used for the wiring 118 that overlaps the wiring 118 that uses an oxide conductive layer.

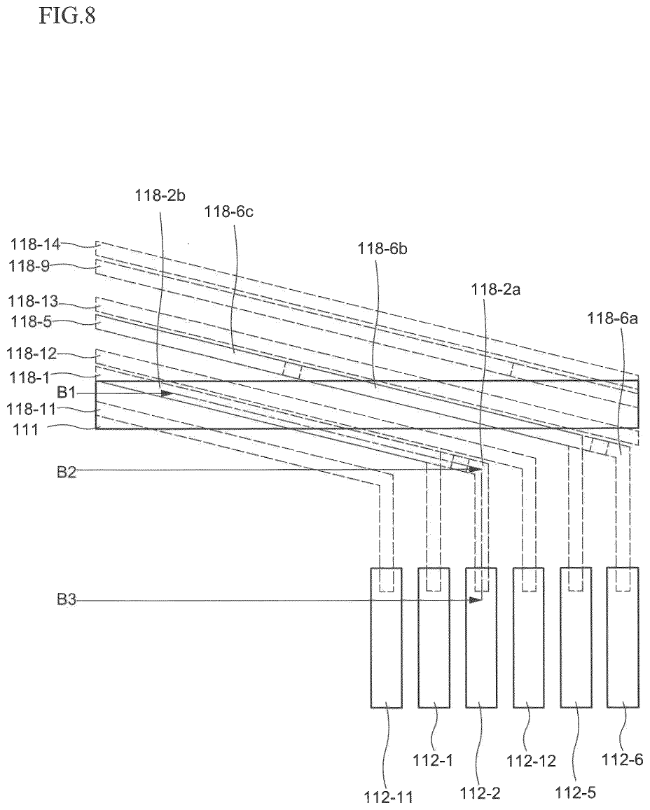

Next, referring to FIG. 8, a modification of the wiring 118 shown in FIG. 7 will be described.

### 5-2. Second Modification

FIG. 8 is a schematic top view showing a terminal of a display device and its periphery according to an embodiment of the present disclosure. Specifically, the configuration of the terminal 112 and the wiring 118 in the region 200 surrounded by the broken line shown in FIG. 1 is shown. Configurations that are the same as or similar to those of display device 10 shown in FIGS. 1 to 7 may be omitted.

The difference from the wiring 118 shown in FIG. 7 is that the wiring 118-2b of the wiring 118-2 overlapping the seal 111 is made of an oxide conductive layer, and the wiring 118-2a is made of metallic material between the wiring 118-2b and the terminal 112-2.

FIG. 8 is a schematic top view showing a terminal of a display device and its periphery according to an embodiment of the present invention. Specifically, FIG. 8 shows the wiring 118-2 including the wiring 118-2a and the wiring 118-2c (not shown) formed of a metallic material and the wiring 118-2b using an oxide conductive layer.

The wiring 118-6 has the same configuration as that of the wiring 118-2. In the wiring 118-6, an oxide conductive layer is used for the wiring 118-6b of a part overlapping the seal 111. The wiring 118-6a made of a metal material is used between the wiring 118-6b and the terminal 112-6, and the wiring 118-6c made of the metal material is connected to one end that differs from the end portion connected to the wiring 118-6a.

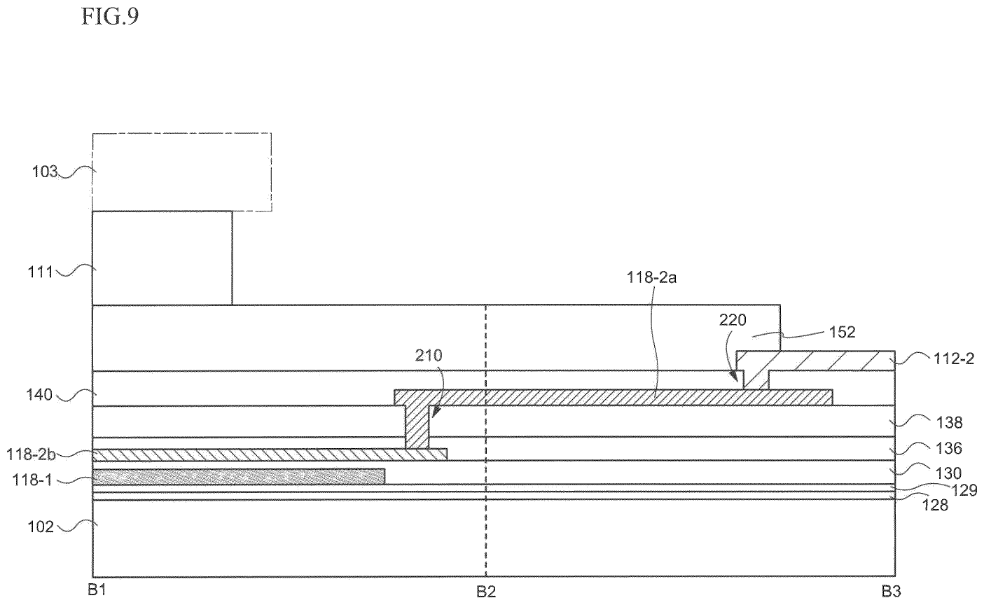

Next, referring to FIG. 9, a cross-sectional configuration of a portion where the wiring 118-2b using an oxide conductive layer and wiring 118-1 formed of a metallic material overlap in a portion overlapping the sealing member 111 will be described.

FIG. 9 is a schematic end view showing a terminal of a display device and its periphery according to an embodiment of the present invention. Specifically, FIG. 9 corresponds to an end view showing a cross section taken along B1-B3 of FIG. 8.

The wiring 118-1 is disposed on the base film 128. The wiring 118-1 is located between the base film 129 and the wiring 118-2b and has the insulating layer 130 between it and the wiring 118-2b. The wiring 118-1 may be formed of the same layers as the bottom gate electrode in the manufacturing process of the transistor constituting the pixel 104 and the scanning line driving circuit 108 or the signal line driving circuit 110. For example, aluminum (Al), titanium (Ti), chromium (Cr), cobalt (Co), nickel (Ni), molybdenum (Mo), hafnium (Hf), tantalum (Ta), tungsten (W), bismuth (Bi), silver (Ag), copper (Cu), and alloys or compounds thereof can be used as the wiring 118-1.

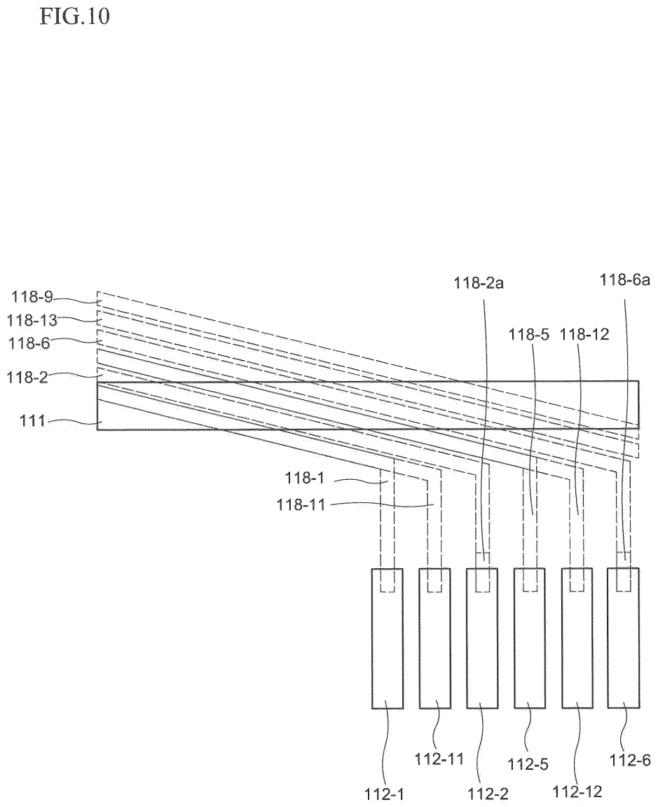

Next, referring to FIG. 10, a modification of the wiring 118 shown in FIG. 7 will be described.

### 5-3. Third Modification

FIG. 10 is a schematic top view showing a terminal of a display device and its periphery according to an embodiment of the present invention. Specifically, a modification of the configuration of the terminal 112 and the wiring 118 in the region 200 surrounded by the broken line shown in FIG. 1 is shown. Configurations that are the same as or similar to those of the display device 10 shown in FIGS. 1 to 9 may be omitted.

The difference from the wiring 118 shown in FIG. 7 is that the wiring 118-1 and the wiring 118-11 overlap. Further, the wiring 118-5 and the wiring 118-12 may further overlap.

As shown in FIG. 10, the wiring 118-1 overlaps the wiring 118-11 in a portion that straddles the seal 111 and a portion that is disposed obliquely with respect to the seal 111. The wiring 118-1 and the wiring 118-11 overlap each other, and the wiring 118-2 using an oxide conductive layer is arranged adjacent to each other. By arranging the wiring 118-1 and the wiring 118-11 with low light transmittance, and the wiring 118-2 with high light transmittance adjacent to each other, there is no need to provide a large distance between the wiring 118. Such an arrangement reduces the number of overlapping wirings 118. Consequently, compared to the height of the overlapped portion of the large number of the wiring 118, the height of the portion with a small number of overlapping wirings 118 is lower than, for example, the height of the portion where the wiring 118-1 and the wiring 118-11 overlap. When the height of the overlapping portion is lowered in this way, it is possible to suppress formation defects of the wiring 118 that occur due to the height of the overlapping portion being high.

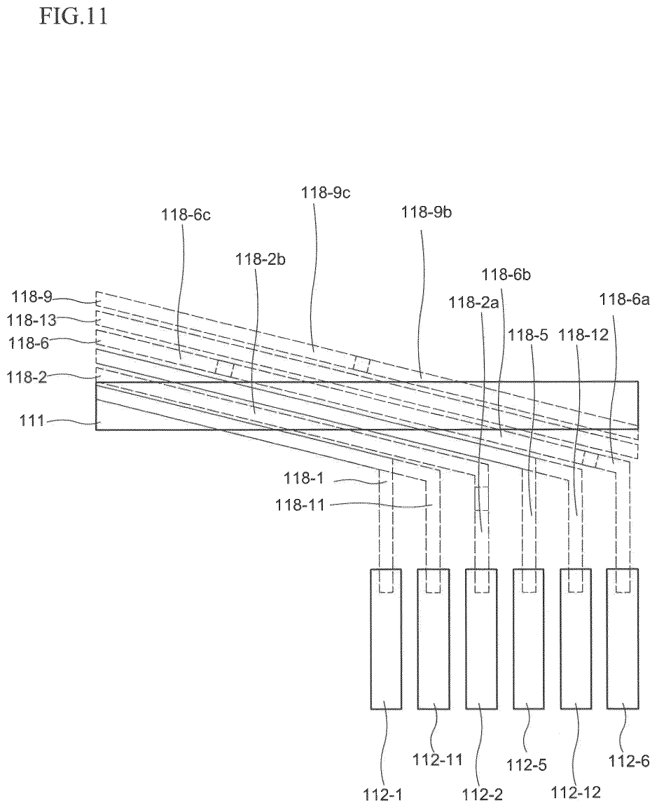

Next, referring to FIG. 11, a modification of the wiring 118 shown in FIG. 10 will be described.

### 5-4. Fourth Modification

FIG. 11 is a schematic top view showing a terminal of a display device and its periphery according to an embodiment of the present invention. Specifically, the configuration of the terminal 112 and the wiring 118 in the region 200 surrounded by the broken line shown in FIG. 1 is shown. Configurations that are the same as or similar to those of display device 10 shown in FIGS. 1 to 10 may be omitted.

The difference from the wiring 118 shown in FIG. 10 is that the wiring 118-2 uses an oxide conductive layer for the wiring 118-2b of the part overlapping the seal 111, and the wiring 118-2a made of a metallic material is used between the wiring 118-2b and the terminal 112-2. One end of the wiring 118-2b is connected to the wiring 118-2a and the other end of the wiring 118-2b is connected to the wiring 118-2c, although not shown.

The wiring 118-6 has the same configuration as that of the wiring 118-2. In the wiring 118-6, an oxide conductive layer is used for the wiring 118-6b of a part overlapping the seal 111. The wiring 118-6a made of a metal material is used between the wiring 118-6b and the terminal 112-6, and the wiring 118-6c made of the metal material is connected to one end that differs from the end portion connected to the wiring 118-6a.

In the display device 10 of the present embodiment, an oxide conductive layer formed in the same manner as the source region 164S and the drain region 164D of the oxide semiconductor layer of the transistor can be used for the wiring 118 connecting the transistor constituting the pixel 104 or the scanning line driving circuit 108 and the signal line driving circuit 110 and the terminal 112 used for connecting the external circuit. Since the oxide conductive layer is highly transparent to light, the seal 111 can be irradiated with light through an oxide conductive layer by using an oxide conductive layer in the wiring 118 overlapping the seal 111, and the seal 111 can be sufficiently cured even in the overlapping part of the wiring. Therefore, the present embodiment can provide a display device in which a defect or degradation due to insufficient curing of the sealing member 111 is suppressed.

Further, the display device 10 of the present embodiment can be narrowed between the plurality of the wirings 118 and can be densely arranged. As a result, the display device 10 of the present embodiment can have a large number of the wirings 118 within a narrow region. Therefore, the present embodiment can realize high definition and a narrow frame.

### SECOND EMBODIMENT

In this embodiment, the configuration of the wiring 218 of the display device 10 according to one embodiment of the present disclosure will be described. One of the differences between the wiring 218 and the wiring 118 of the first embodiment is that the plurality of the wirings 218 formed of a metal material is arranged next to each other, and the wiring 218 using an oxide conductive layer overlaps at least one of the wirings 218 formed of a plurality of metal materials. Descriptions of the same or similar configurations as those of the first embodiment will be omitted in some cases.

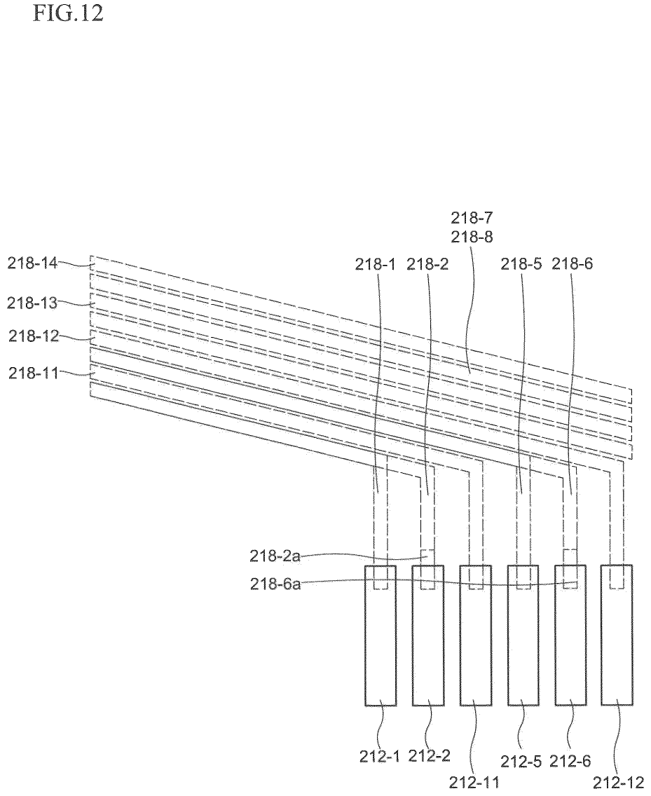

FIG. 12 is a schematic top view showing a terminal of a display device and its periphery according to an embodiment of the present invention. An automatic gain control voltage is input to the terminal 212-2 and the terminal 212-5 shown in FIG. 12, a video signal is supplied to the terminal 212-2 and the terminal 212-6, and a scanning signal is supplied to the terminal 212-11 and the terminal 212-12.

The wiring 218-1 and the wiring 218-5 are connected to the terminal 212-1 and the terminal 212-5, respectively. The wiring 218-2 and the wiring 218-6 are connected to the terminal 212-2 and the terminal 212-6, respectively. The wiring 218-11 and the wiring 218-12 are connected to the terminal 212-11 and the terminal 212-12, respectively.

The wiring 218-1, the wiring 218-5, the wiring 218-11, and the wiring 218-12 are wirings formed of metallic materials. The oxide conductive layer is used for the wiring 218-2 and the wiring 218-6. The wiring 218-2 and the wiring 218-6 are connected to the terminal 212-2 and the terminal 212-6 via the wiring 218-2a and the wiring 218-6a made of metallic materials, respectively.

The wiring 218-1 and the wiring 218-2 may overlap each other in a part extending in an oblique direction with respect to the direction in which the plurality of the terminals 212 is arranged. However, depending on the routing method of the wiring 218, the wiring 218-1 and the wiring 218-2 can overlap each other even when the plurality of the terminals 212 extends substantially perpendicular or parallel to the arrangement direction. The wiring 218-5 and the wiring 218-6 can be arranged in the same manner as the wiring 218-1 and the wiring 218-2.

The wiring 218-11 is disposed between the wiring 218-2 and the wiring 218-6. The wiring 218-12 is also positioned between the wiring 218-2 and the wiring 218-6.

As described above, the wiring 218-1 made of the metal material and the wiring 218-2 using an oxide conductive layer can overlap, and the wiring 218-11 made of the metal material can be disposed close to the wiring 218-1 and the wiring 218-2 to overlap, as shown in FIG. 12.

An oxide conductive layer used in the wiring 218-2 is formed in the same process as the oxide semiconductor layers that are active layers of the transistors constituting the pixel 104 or the scanning line driving circuit 108 and the signal line driving circuit 110. Therefore, the film thickness of the oxide conductive layer is smaller than the film thicknesses of the wiring 218-1 and the wiring 218-11. As described above, when the wiring 218-1 made of a metal material and the wiring 218-2 using an oxide conductive layer overlap, the height of the overlapping portion can be significantly lower than the height of the overlapping portion when the wiring 218-1 and the wiring 218-11 made of a metal material overlap.

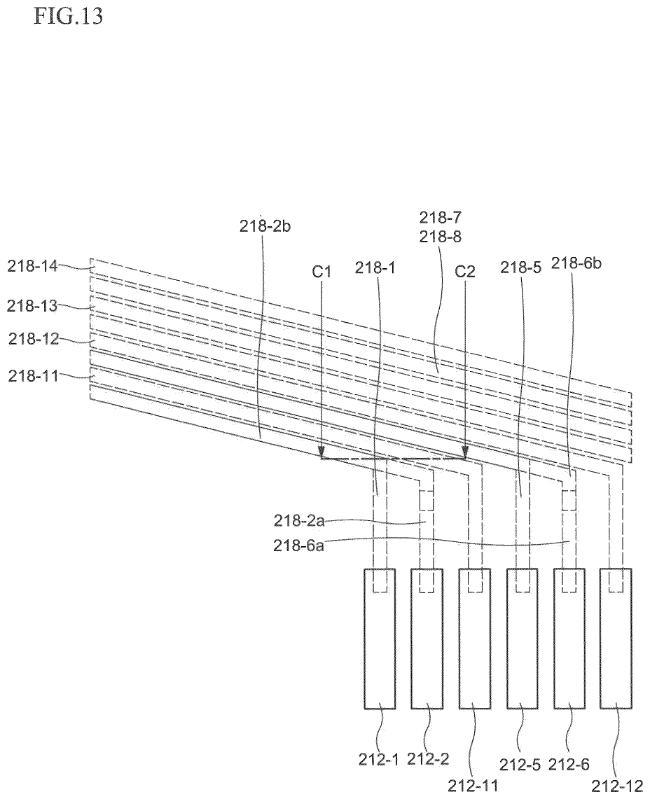

Next, referring to FIG. 13, a modification of the wiring 218 shown in FIG. 12 will be described.

FIG. 13 is a schematic top view showing a terminal of a display device and its periphery according to an embodiment of the present invention. Specifically, the configuration of the terminal 212 corresponding to the terminal 112 and the wiring 218 corresponding to the wiring 118 in the region 200 surrounded by the broken line shown in FIG. 1 is shown. Configurations that are the same as or similar to those of display device 10 shown in FIGS. 1 to 12 may be omitted.

The wiring 218-2 differs from FIG. 12 in that an oxide conductive layer is used as the overlapping part of the wiring 218-1 and the wiring 218-2b is used as the overlapping part, and the wiring 218-2a is used as the non-overlapping part of the wiring 218-1. As shown in FIG. 13, the wiring 218-2 around the terminal 212 uses the wiring 218-2a made of a metallic material in a part not overlapping the wiring 218-1. Although not shown, the wiring 218-2c made of a metallic material may be used in a part that does not overlap the wiring 218-1 between the transistor constituting the pixel 104 and the scanning line driving circuit 108 or the signal line driving circuit 110 and the terminal 212.

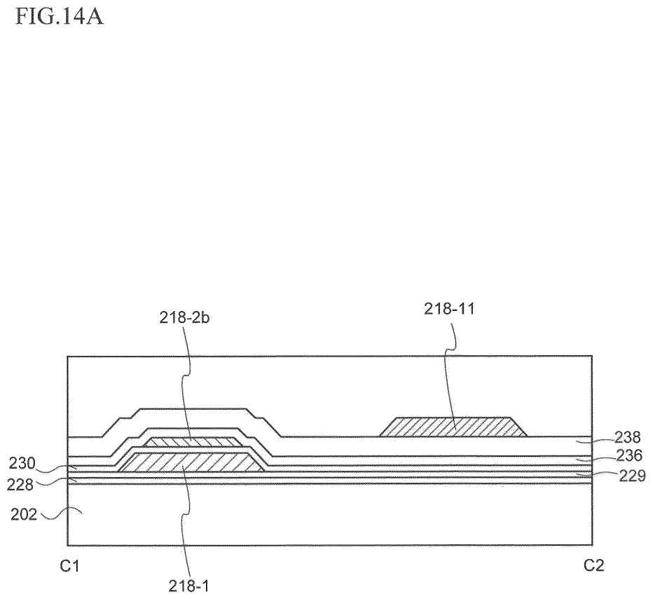

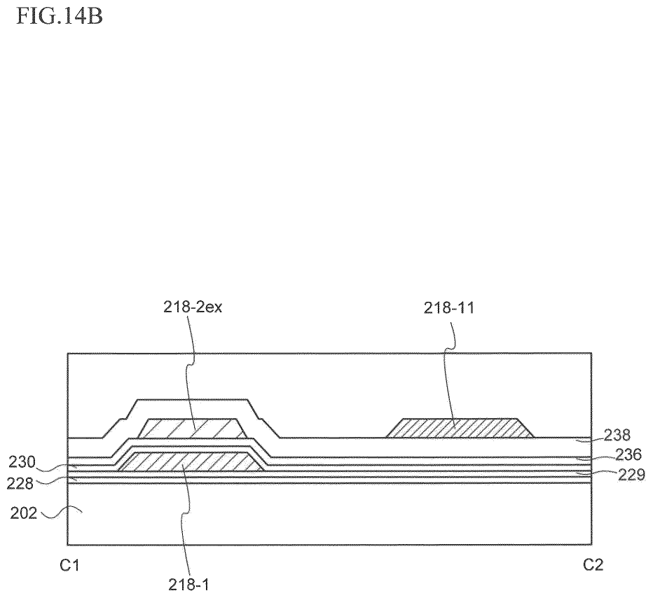

Now, referring to FIGS. 14A and 14B, a cross-sectional configuration of a part where the wiring 218-2 overlaps the wiring 218-1 will be described.

FIG. 14A is a schematic end view of a periphery of a terminal of a display device according to an embodiment of the present invention. Specifically, FIG. 14A corresponds to an end view showing a cross section taken along C1-C2 of FIG. 13. FIG. 14B is a schematic end view showing the periphery of the terminal of display device according to the comparative embodiment. As a display device according to the comparative example, the wiring 218-2 overlapping the wiring 218-1 was used.

FIG. 14A shows an example of the present embodiment, in which the wiring 218-2b is arranged on top of the wiring 218-1. FIG. 14B shows a comparative example in which the wiring 218-2ex made of a metallic material is arranged on top of the wiring 218-1.

When the height of the portion where the wiring 218-1 and the wiring 218-2b shown in 14A are stacked is compared with the height of the portion where the wiring 218-1 and the wiring 218-2ex shown in 14B are stacked in an overlapping manner, the portion overlapping the wiring 218-2b is lower than the height of the portion where the wiring 218-2ex overlaps and is stacked.

Further, comparing the unevenness of the insulating layer 238 shown in FIG. 14A and the unevenness of the insulating layer 238 shown in FIG. 14B, it can be seen that the unevenness of the insulating layer 238 shown in FIG. 14B is large. This unevenness greatly affects the manufacturing process after the wiring 218 is formed or after the insulating layer 238 is formed, and mainly causes formation defects such as wiring. In particular, in wiring formation defects, the metal material used in wiring has not been completely removed at locations other than the patterning, and the metal material that could not be removed may cause wiring to short-circuit.

In the display device 10 of the present embodiment, an oxide conductive layer having a thickness equivalent to that of oxide semiconductor layers of the transistor can be used for the wiring 218-2. As a result, the overlapping part of the wiring 218-2 and the wiring 218-1 can have less impact on the subsequent process after the wiring 218-2 is formed. Therefore, according to the present embodiment, it is possible to provide a display device in which there a few defects and degradation is suppressed.

In the display device 10 of the present embodiment, the region occupied by the plurality of the wirings 218 in a display device can be reduced by providing the plurality of the wirings 218 in a stacked manner. Therefore, the present embodiment can provide a display device with a narrowed frame.

Further, in the display device 10 of the present embodiment, a high-definition display device can be provided because it is possible to arrange more wiring 218 in a display device by providing the plurality of the wirings 218 in a stacked manner.

Each of the embodiments described above as the embodiment of the present invention can be appropriately combined as long as no contradiction is caused. In addition, the addition, deletion, or design change of components, or the addition, deletion, or condition change of processes as appropriate by those skilled in the art based on each embodiment are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A display device comprising:
a plurality of transistors having an oxide semiconductor layer;
a first terminal electrically connected to the plurality of transistors;
a second terminal electrically connected to the plurality of transistors and adjacent to the first terminal;
a first wiring electrically connected to the plurality of transistors and the first terminal and located between the plurality of transistors and the first terminal; and
a second wiring electrically connected to the plurality of transistors and the second terminal and located between the plurality of transistors and the second terminal, wherein
the first wiring is formed of a metallic material, and
the second wiring includes an oxide conductive layer having the same composition as the oxide semiconductor layer.

2. The display device according to claim 1, further comprising,
a plurality of pixels in which at least one of the plurality of transistors is arranged respectively, and
a seal surrounding the plurality of pixels, wherein
the seal overlaps the second wiring.

3. The display device according to claim 2, wherein
the second wiring further comprises a third wiring and a fourth wiring formed of a metallic material and a fifth wiring located between the third wiring and the fourth wiring,
the fifth wiring is located between the third wiring and the fourth wiring,
the third wiring is connected to the second terminal,
the fourth wiring is connected to the plurality of transistors, and
the seal overlaps the fifth wiring.

4. The display device according to claim 1, wherein
the second wiring and the first wiring overlap.

5. The display device according to claim 4, further comprising,
a substrate on which the plurality of transistors is arranged, wherein
the first wiring is arranged in the layer between the substrate and the oxide semiconductor layer.

6. The display device according to claim 5, further comprising,
a third terminal electrically connected to the plurality of transistors and adjacent to the first terminal; and
a sixth wiring located between the plurality of transistors and the third terminal and electrically connected to the plurality of transistors and the third terminal,
wherein
the plurality of transistors includes the oxide semiconductor layer between the substrate and the gate electrode,
the gate electrode and the sixth wiring are electrically connected, and
the sixth wiring and the second wiring are positioned next to each other.

7. The display device according to claim 6, wherein
the sixth wiring overlaps the first wiring.

8. The display device according to claim 7, further comprising,
a plurality of pixels in which at least one of the plurality of transistors is arranged respectively; and
a seal surrounding the plurality of pixels, wherein
the second wiring further includes a third wiring and a fourth wiring formed of a metallic material, and a fifth wiring located between the third wiring and the fourth wiring,
the third wiring is connected to the second terminal,
the fourth wiring is connected to the plurality of transistors, and
the seal overlaps the fifth wiring.

9. The display device according to claim 1, wherein
the oxide semiconductor layer includes a channel region, a source region and a drain region sandwiching the channel region; and
the oxide conductive layer includes the same impurity element as the source region and the drain region.

10. The display device according to claim 9, wherein
the second wiring is electrically connected to the source or the drain region.
